(19) United States
(12) Patent Application Publication
(10) Pub. No.: US 2010/0072542 A1
(43) Pub. Date: Mar. 25, 2010

(54) SEMICONDUCTOR DEVICE, METHOD FOR MANUFACTURING THE SAME, AND DATA PROCESSING SYSTEM

(75) Inventors: Tomohiro Kadoya, Tokyo (JP); Kazuma Shimamoto, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/585,361

(22) Filed: Sep. 14, 2009

(30) Foreign Application Priority Data
Sep. 22, 2008 (JP) 2008-242378
Jul. 15, 2009 (JP) 2009-166633

(51) Int. Cl. H01L 29/78; H01L 29/06; H01L 21/762

(52) U.S. Cl. 257/330; 257/506; 438/424; 257/E29.262; 257/E29.02; 257/E21.545

(57) ABSTRACT

Modification of an SOD film is promoted in a hot oxidizing atmosphere. Elements under a liner film and a semiconductor substrate are prevented from being damaged by oxidation.

A semiconductor device includes a recess portion, a first liner film and a second liner film sequentially formed on inner wall side surfaces of the recess portion, the second liner film containing an oxygen atom, and an insulating region filled in the recess portion. The first liner film has a higher oxidation resistance than the second liner film.

This application is based upon and claims the benefit of priority from Japanese Patent Application No. 2008-242378, filed on Sep. 22, 2008, and Japanese Patent Application No. 2009-166633, filed on Jul. 15, 2009, the disclosure of which is incorporated herein in its entirety by reference.

### BACKGROUND OF THE INVENTION

1. Field of the Invention

The present invention relates to a semiconductor device, a method for manufacturing the same, and a data processing system

2. Description of the Related Art

As means for forming an insulating film over a wiring layer and a trench portion formed on a semiconductor substrate, a method is known which uses a coating film such as an SOG (Spin On Glass) film for flattening. In recent years, efforts have been made to develop low dielectric-constant coating insulating films. The term “SOD (Spin On Dielectrics) film” has more commonly been used to express coating insulating films including SOG films. Thus, in the description below, the term “SOD film” is used as a coating insulating film obtained by using a rotary coating method such as a spin coating method or a spray coating method to apply a solution containing an insulating material and then carrying out thermal treatment.

An example of a typical material for the SOD film is polysilazane. Polysilazane is a polymer material also called a silazane polymer and having —(SiH₂—NH)— as a basic structure. Polysilazane is dissolved into a solvent (xylene, di-n-butylether, or the like) for use. The silazane polymer contains a substance obtained by replacing hydrogen with another functional group such as a methoxy group. Furthermore, a polymer with no functional group or modified group addition is called perhydro polysilazane.

As described in Japanese Patent Laid-Open No. 11-74262, polysilazane or the like can be converted (modified) into an SOD film (solid) with dense film quality by, after coating, being subjected to thermal treatment in a hot oxidizing atmosphere.

As described in Japanese Patent Laid-Open Nos. 2000-216273 and 2004-311487, when the thermal treatment is carried out in the oxidizing atmosphere, a common method for inhibiting an under film from being affected involves providing a silicon nitride film (Si₃N₄) serving as a liner film and coating an SOD film material on the silicon nitride film.

### SUMMARY OF THE INVENTION

In one embodiment, there is provided a semiconductor device comprising:

a recess portion;

a first liner film formed on opposite inner wall side surfaces and a bottom surface of the recess portion;

a second liner film formed on the first liner film in the recess portion; and

an insulating region comprising an SOD film filled in the recess portion,

wherein the second liner film contains an oxygen atom, and the first liner film has a higher oxidation resistance than the second liner film.

In another embodiment, there is provided a semiconductor device comprising:

a semiconductor substrate; and

an isolation region formed in the semiconductor substrate,

wherein the isolation region comprises a first liner film formed so as to continuously cover at least a part of an inner wall of a trench formed in the semiconductor substrate, a second liner film provided on the first liner film and containing an oxygen atom, and an insulating region comprising an SOD film filled in at least a part of an inside of the trench so as to be in contact with the second liner film, and

the first liner film has a higher oxidation resistance than the second liner film.

In another embodiment, there is provided a method for manufacturing a semiconductor device, comprising:

forming a recess portion;

forming a first liner film covering opposite inner wall side surfaces and a bottom surface of the recess portion;

forming a second liner film covering the first liner film; and

filling an SOD film covering the second liner film in the recess portion,

wherein the second liner film contains an oxygen atom, and

the first liner film has a higher oxidation resistance than the second liner film.

In another embodiment, there is provided a data processing system including an arithmetic processing device, wherein the arithmetic processing device comprises:

a recess portion;

a first liner film formed on opposite inner wall side surfaces and a bottom surface of the recess portion;

a second liner film formed on the first liner film in the recess portion; and

an insulating region comprising an SOD film filled in the recess portion,

wherein the second liner film contains an oxygen atom, and the first liner film has a higher oxidation resistance than the second liner film.

In the specification, the term “predetermined plane” refers to any plane in a semiconductor substrate. A semiconductor protruding portion present on the predetermined plane in the semiconductor substrate may be composed of the same material as that of the semiconductor substrate.

The term “base” refers to a structure including any plane. The base may be composed of a plurality of layers or regions.

The term “recess portion” refers to a recessed shape formed by two inner wall surfaces that are at least arranged opposite each other. The recess portion may or may not be formed so as to be entirely surrounded by the inner wall surfaces. That is, the inner wall surface may be omitted from any part of the recess portion; that part of the recess portion may be open.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram showing a part of a process of manufacturing a semiconductor device according to a first exemplary embodiment;

FIG. 2 is a diagram showing a part of the process of manufacturing the semiconductor device according to the first exemplary embodiment;

FIG. 3 is a diagram showing a semiconductor device according to the first exemplary embodiment;

FIG. 4 is a diagram showing a part of a process of manufacturing a semiconductor device according to a second exemplary embodiment;

FIG. 5 is a diagram showing a part of the process of manufacturing the semiconductor device according to the second exemplary embodiment;

FIG. 6 is a diagram showing a part of the process of manufacturing the semiconductor device according to the second exemplary embodiment;

FIG. 7 is a diagram showing a part of the process of manufacturing the semiconductor device according to the second exemplary embodiment;

FIG. 8 is a diagram showing a part of the process of manufacturing the semiconductor device according to the second exemplary embodiment;

FIG. 9 is a diagram showing a part of the process of manufacturing the semiconductor device according to the second exemplary embodiment;

FIG. 10 is a diagram showing a semiconductor device according to the second exemplary embodiment;

FIG. 11 is a diagram showing a part of a process of manufacturing a semiconductor device according to a third exemplary embodiment;

FIG. 12 is a diagram showing a part of the process of manufacturing the semiconductor device according to the third exemplary embodiment;

FIG. 13 is a diagram showing a part of the process of manufacturing the semiconductor device according to the third exemplary embodiment;

FIG. 14 is a diagram showing a semiconductor device according to the third exemplary embodiment;

FIG. 15 is a diagram showing a part of the process of manufacturing the semiconductor device according to the second exemplary embodiment;

FIG. 16 is a diagram showing a variation of the semiconductor device according to the second exemplary embodiment;

FIG. 17 is a diagram showing a part of a process of manufacturing a semiconductor device according to a fourth exemplary embodiment;

FIG. 18 is a diagram showing a part of the process of manufacturing the semiconductor device according to the fourth exemplary embodiment;

FIG. 19 is a diagram showing a part of the process of manufacturing the semiconductor device according to the fourth exemplary embodiment;

FIG. 20 is a diagram showing a part of the process of manufacturing the semiconductor device according to the fourth exemplary embodiment;

FIG. 21 is a diagram showing a part of the process of manufacturing the semiconductor device according to the fourth exemplary embodiment;

FIG. 22 is a diagram showing a part of the process of manufacturing the semiconductor device according to the fourth exemplary embodiment;

FIG. 23 is a diagram showing a semiconductor device according to a fifth exemplary embodiment; and

FIG. 24 is a diagram showing the semiconductor device according to the fifth exemplary embodiment.

In the drawing, numerals have the following meanings. 1: semiconductor substrate, 2: interlayer insulating film, 3: wiring layer, 4: silicon nitride film, 5: silicon oxynitride film, 6: SOD film, 200: semiconductor substrate, 201: MOS transistor, 202: gate insulating film, 203: isolation region, 204: active region, 205: N-type impurity layer, 206: gate electrode, 207: cap insulating film, 208: side wall, 210, 211, 212: contact plugs, 220: silicon nitride film, 221: silicon oxynitride film, 222: liner film, 223: SOD film, 230: contact plug, 231: wiring layer, 236: interlayer insulating film, 240, 241: contact plugs, 245: capacitor element, 246: interlayer insulating film, 256: interlayer insulating film, 257: wiring layer, 260: surface protection film, 300: semiconductor substrate, 301: silicon oxide film, 302: mask film, 303: trench, 304: silicon nitride film, 305: silicon oxynitride film, 306: SOD film, 350: semiconductor substrate, 351: P-type well, 352: N-type well, 355: isolation region, 360: gate insulating film, 361: gate electrode, 365: P-type source and drain regions, 366: N-type source and drain regions, 370: interlayer insulating film, 380a, 380b: contact plugs, 381a, 381b: wiring layers, 390: surface protection film, 400: semiconductor substrate, 401, 407, 410: silicon oxide film, 402: mask film, 403: trench, 404: silicon nitride film, 405: silicon oxynitride film, 406: SOD film, 500: data processing system, 510: system bus, 520: arithmetic processing device, 530: RAM, 540: ROM, 550: nonvolatile storage device, 560: I/O device.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

A specific example will be described below in which an interlayer insulating film is formed between wiring layers

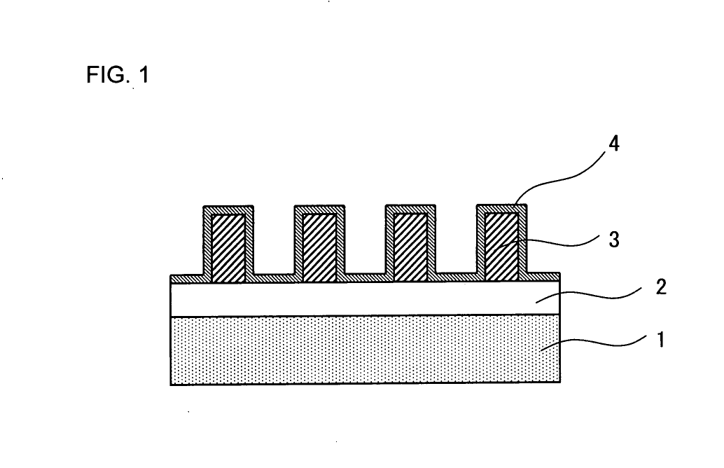

FIGS. 1 to 3 are sectional views showing a method for manufacturing a semiconductor device according to a first exemplary embodiment. First, as shown in FIG. 1, interlayer insulating film 2 such as a silicon oxide film (SiO₂) is formed on semiconductor substrate 1 such as silicon. A pattern for wiring layer 3 is formed on the interlayer insulating film using a high melting-point metal such as tungsten (W). Silicon nitride film (Si₃N₄) 4 is thereafter formed over the surface of wiring layer 3 to a thickness of 3 to 6 nm using a CVD method. Silicon nitride film 4 corresponds to a first liner film that is a lower layer portion of a liner film.

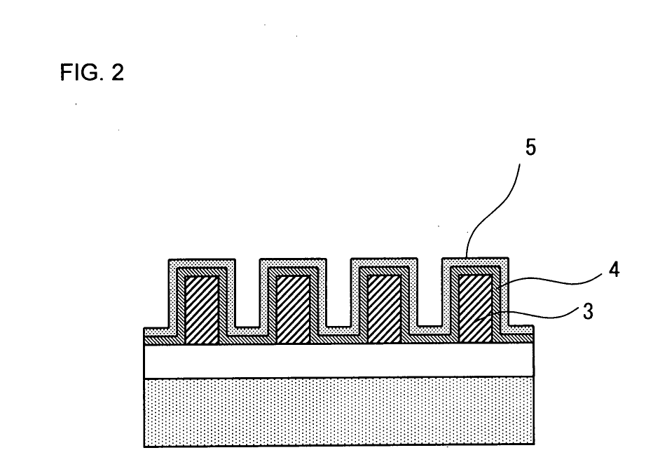

Then, as shown in FIG. 2, silicon oxynitride film (SiON) 5 is formed on silicon nitride film 4 to a thickness of 3 to 10 nm using the CVD method. Specifically, silicon oxynitride film 5 can be formed by allowing a material gas containing dichlorosilane (DCS), nitrous oxide (N₂O), and ammonia (NH₃) to react at elevated temperature and reduced pressure. Silicon oxynitride film 5 corresponds to a second liner film that is an upper layer portion of the liner film.

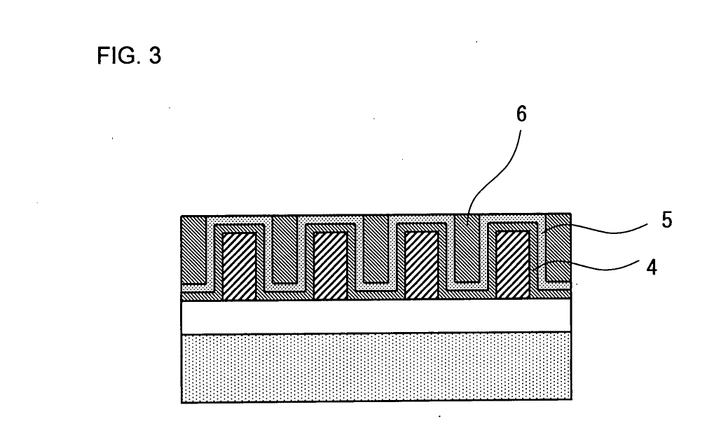

Then, as shown in FIG. 3, SOD film material 6 such as polysilazane is coated so as to be filled into the spaces in wiring layer 3. Thermal treatment is thereafter carried out at 700° C. for 60 minutes in an oxidizing atmosphere containing H₂O to solidify SOD film material 6 to form an SOD film. At this time, oxygen is fed to SOD film material 6 not only through the top surface thereof but also through silicon oxynitride film 5 which is in contact with SOD film material 6 at the bottom and side surfaces thereof. Thus, the SOD film material 6 is fully modified and converted into an insulating film with a dense film quality. Furthermore, the nitrogen content of silicon oxynitride film 5 is smaller than that of silicon nitride film 4. Silicon oxynitride film 5 is thus effective for inhibiting generation of ammonia gas desorbed from the surface of the film during the thermal treatment. Consequently, the modification progresses without hindering the substitution of the SOD film material into an Si—O bond.

Furthermore, in the present exemplary embodiment, silicon nitride film 4 is provided in the lower layer portion of the liner film. The silicon nitride film is unlikely to allow oxygen to pass through and is excellent in resistance to oxidation. Thus, even if elements (not shown in the drawings) already provided in semiconductor substrate 1 and the layer under wiring layer 3 are exposed to a hot oxidizing atmosphere for a long time, the elements can be prevented from being oxidized.

That is, in the present exemplary embodiment, the liner film includes a two-layer structure and thus functions as both a barrier film and an oxygen supply source.

After the modification of the SOD film, if necessary, the top surface portion of the resulting structure may be flattened by etchback or CMP (Chemical Mechanical Polishing). For CMP, a protective cap insulating film may be provided on the wiring layer beforehand.

Thereafter, a further upper wiring layer, contact plugs, and the like are formed to complete a semiconductor device according to the first exemplary embodiment.

### Second Exemplary Embodiment

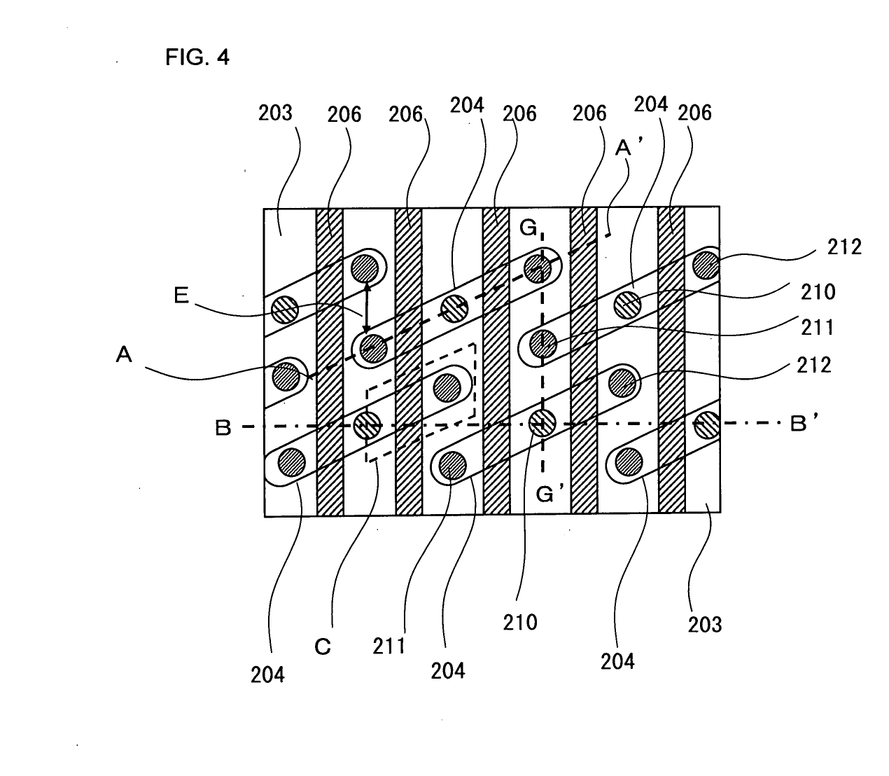

With reference to FIGS. 4 to 10, a manufacturing method for memory cells in a DRAM will be described.

FIG. 4 is a plan view schematically showing a part of a memory cell in a DRAM according to a second exemplary embodiment. For simplification of description, portions relating to a capacitor are omitted from the drawings. In FIG. 4, a plurality of active regions (diffusion layer regions; the active regions correspond to semiconductor protruding portions) 204 are regularly arranged on the semiconductor substrate (not shown in the drawing). Active regions 204 are partitioned by isolation regions 203. Isolation regions 203 are formed by an STI (Shallow Trench Isolation) method using an insulating film (separating insulating film) such as a silicon oxide film. A plurality of gate electrodes 206 are arranged so as to cross active regions 204. Gate electrodes 206 function as word lines for the DRAM. Impurities such as phosphorous are ion-implanted in portions of each active region 204 which is not covered with gate electrodes 206, thus forming an N-type impurity layer. The N-type impurity layer functions as source/drain regions for a transistor.

A portion enclosed by dashed line C in FIG. 4 forms one MOS transistor (field effect transistor). Contact plug 210 is provided in the central portion of each active region 204 in contact with the N-type impurity layer on a surface portion of active region 204. Furthermore, contact plugs 211 and 212 are provided on the opposite ends of each active region 204 in contact with the N-type impurity layer on the surface of active region 204. The contact plugs are sandwiched between opposite gate electrodes 206. Contact plugs 210, 211, and 212 are shown by different item numbers for description but can be simultaneously formed during actual manufacture.

In this layout, to allow the memory cells to be densely arranged, two adjacent MOS transistors are arranged so as to share one contact plug 210.

In a subsequent step, a wiring layer (not shown in the drawings) is formed in contact with contact plugs 210 in a direction orthogonal to gate electrode 206 as shown by line B-B′. The wiring layer functions as a bit line for the DRAM. Furthermore, a capacitor element (not shown in the drawings) is connected to each of contact plugs 211 and 212.

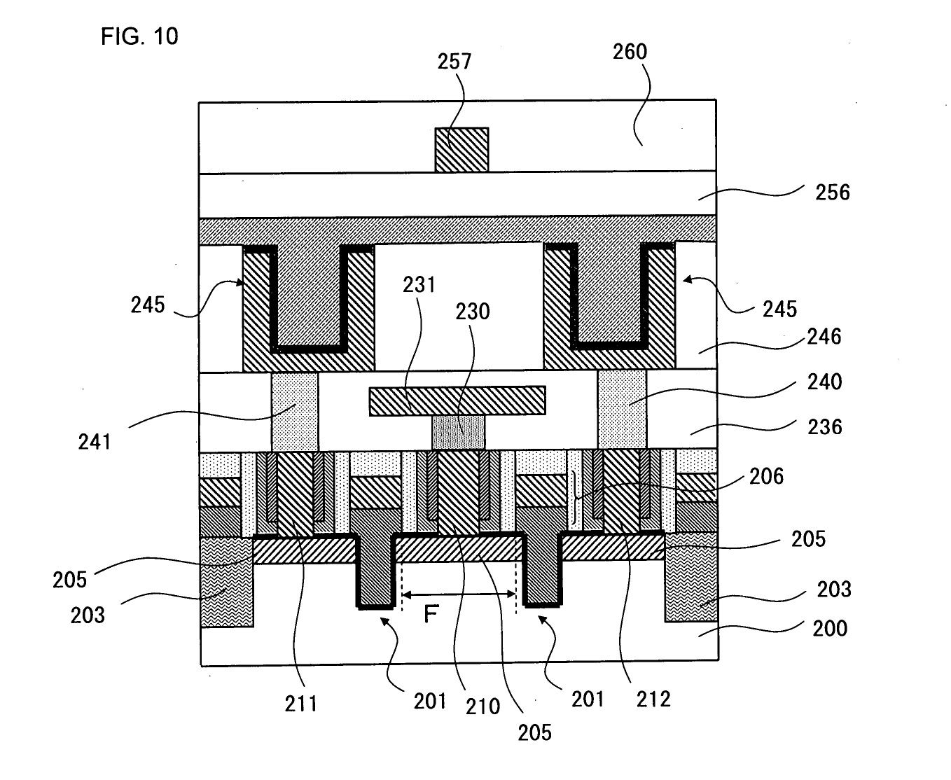

A sectional view of a memory cell in a completed DRAM is shown in FIG. 10. FIG. 10 corresponds to a cross section taken along line A-A′ in FIG. 4. In FIG. 10, reference numeral 200 denotes a semiconductor substrate made up of P-type silicon. Reference numeral 201 denotes an N-type MOS transistor including gate electrode 206. A part of gate electrode 206 is configured to fill a trench portion formed in semiconductor substrate 200. Gate electrode 206 functions as a word line. N-type impurity layer 205 is formed on the surface portion of active region 204. MOS transistor 201 forms a recess channel type transistor. N-type impurity layer 205 is in contact with contact plugs 210, 211, and 212. Polycrystalline silicon doped with phosphorous can be used as a material for contact plugs 210, 211, and 212.

Contact plug 210 is connected, via separate contact plug 230, to wiring layer 231 functioning as a bit line. Tungsten (W) can be used as a material for wiring layer 231. Furthermore, contact plugs 211 and 212 are connected to capacitor element 245 via separate contact plugs 241 and 240, respectively. Reference numerals 236, 246, and 256 denote interlayer insulating films insulating wires. Capacitor element 245 is formed by well-known means so as to sandwich an insulating film such as hafnium oxide (HfO) between two electrodes. Reference numeral 257 denotes a wiring layer formed using aluminum or the like and located in a top layer. Reference numeral 260 denotes a surface protection film.

In the memory cell in the DRAM, whether any charge is accumulated in capacitor element 245 can be determined via the bit line (wiring layer 231) by turning on MOS transistor 201. Thus, the structure illustrated in FIG. 10 operates as a DRAM memory cell capable of performing an operation of storing information.

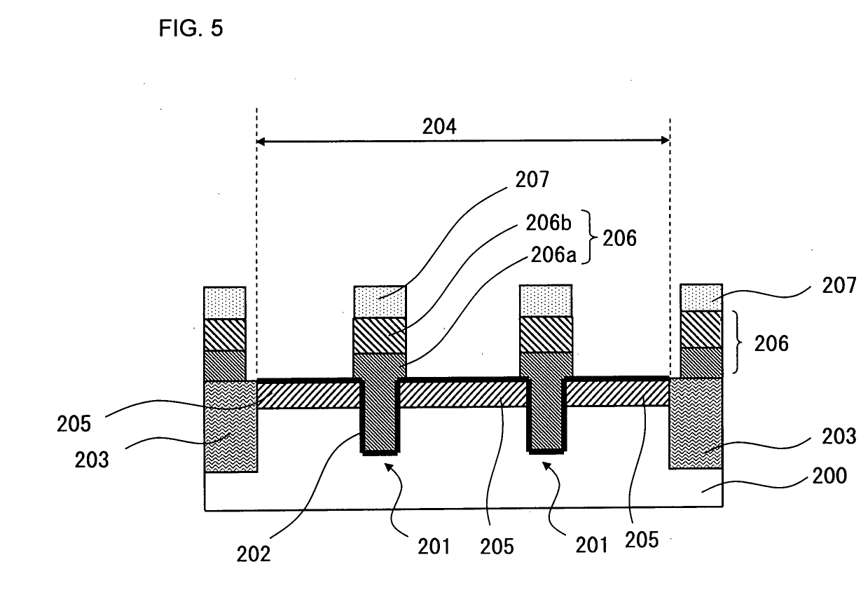

A method for manufacturing the DRAM will be described with reference to FIGS. 5 to 9. FIGS. 5 to 9 are sectional views taken at the same position as that in FIG. 10. First, as shown in FIG. 5, isolation regions 203 are formed on semiconductor substrate 200 made up of P-type silicon, using an insulating film such as a silicon oxide film. Isolation regions 203 partition semiconductor substrate 200 into active regions 204.

Gate electrode 206 in the MOS transistor is formed of a stack film of polycrystalline silicon film 206a doped with impurities and high melting-point metal film 206b such as tungsten. The lower layer portion of polycrystalline silicon film fills a trench portion formed by removing semiconductor substrate 200 from the inside of corresponding active region 204. Gate insulating film 202 such as a silicon oxide film is formed in an interface portion between gate electrode 206 and semiconductor substrate 200. Furthermore, cap insulating film 207 protecting the top surface of gate electrode 206 is formed using a silicon nitride film. Cap insulating film 207 is formed by patterning performed simultaneously with patterning of gate electrode 206.

N-type impurity layer 205 is formed on the respective opposite sides of gate electrode 206 by ion implantation of N-type impurities such as phosphorous. N-type impurity layer 205 functions as source/drain regions for MOS transistor 201.

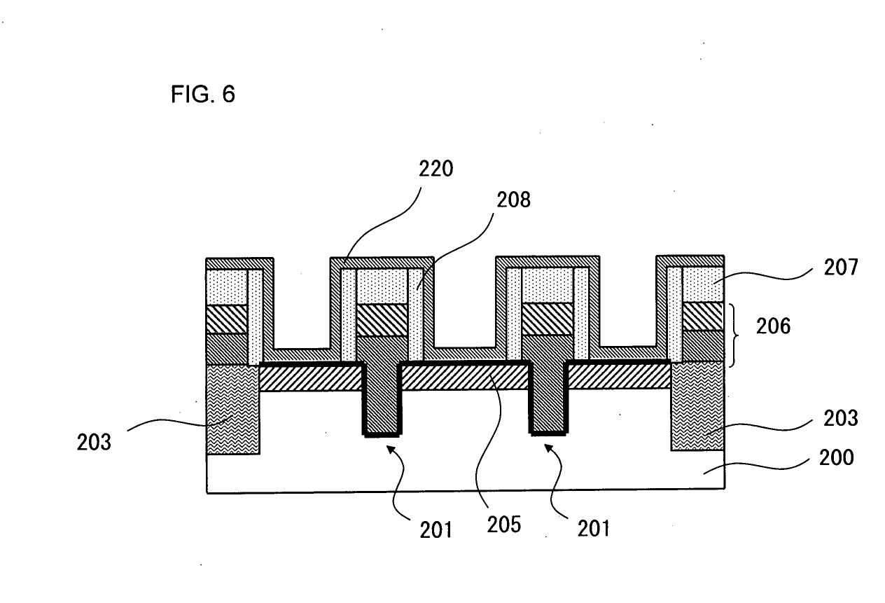

Then, as shown in FIG. 6, side walls 208 are formed using an insulating film such as a silicon nitride film so as to cover the side surface portions of gate electrode 206 and cap insulating film 207. Thereafter, silicon nitride film 220 is formed all over the surface of semiconductor substrate 200 to a thickness of 3 to 6 nm.

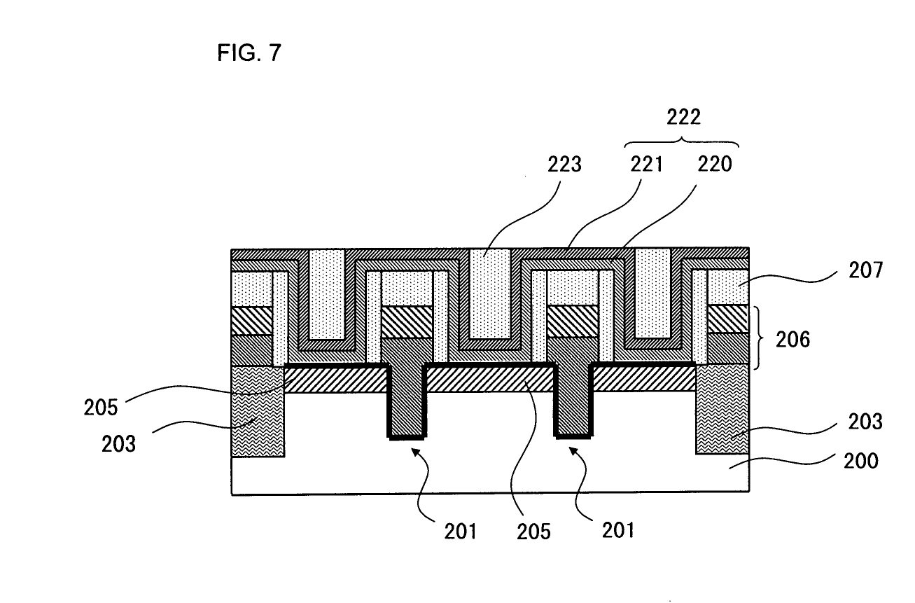

Then, as shown in FIG. 7, silicon oxynitride film (SiON) 221 is formed on silicon nitride film 220 to a thickness of 3 to 10 nm. Thus, liner film 222 of a stack structure is formed. Silicon nitride film 220 corresponds to a first liner film, and silicon oxynitride film 221 corresponds to a second liner film. Alternatively, with side walls 208 already formed, first, a thin film (about 5 to 10 nm) made up of an insulating film such as a silicon oxide film may be formed, and then a first liner film may be formed on the thin film.

Thereafter, SOD film material 223 such as polysilazane is coated so as to be filled into a space portion of each gate electrode 206. Thermal treatment is thereafter carried out at 700° C. for 60 minutes in an oxidizing atmosphere containing H₂O. Thus, oxygen is fed to SOD film material 223 not only through the top surface thereof but also through silicon oxynitride film 221 which is in contact with SOD film material 223 at the bottom and side surfaces thereof. Consequently, SOD film material 223 is fully modified and converted into a solid film with a dense film quality. Furthermore, in this case, gate electrode 206 and semiconductor substrate 200 are covered with silicon nitride film 220 that is excellent in resistance to oxidation and are thus prevented from being degraded by the oxidizing atmosphere even during the thermal treatment.

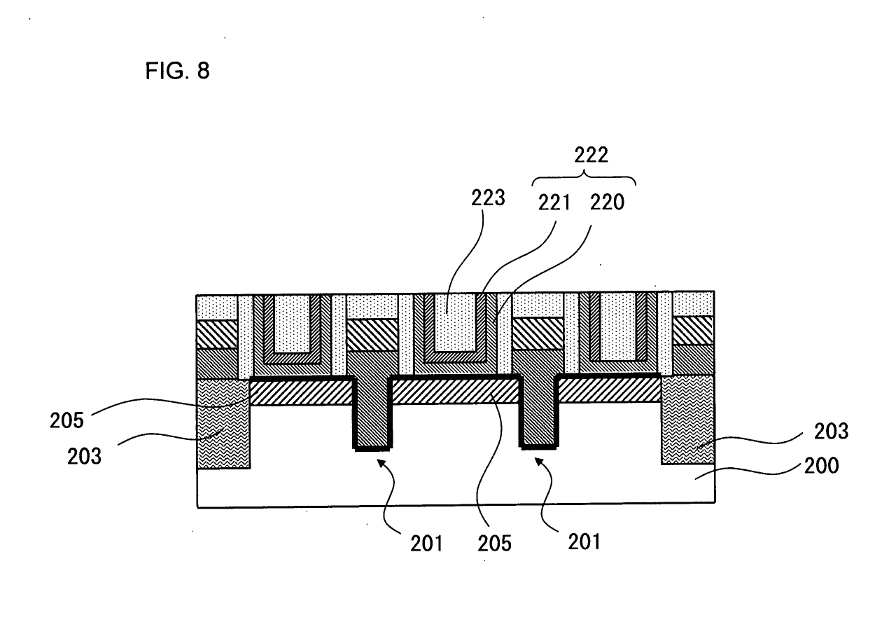

Then, as shown in FIG. 8, the top surface of the resulting structure is flattened by a CMP method. At this time, no problem occurs even if liner film 222, cap insulating film 207, or side wall 208 is partly removed by polishing.

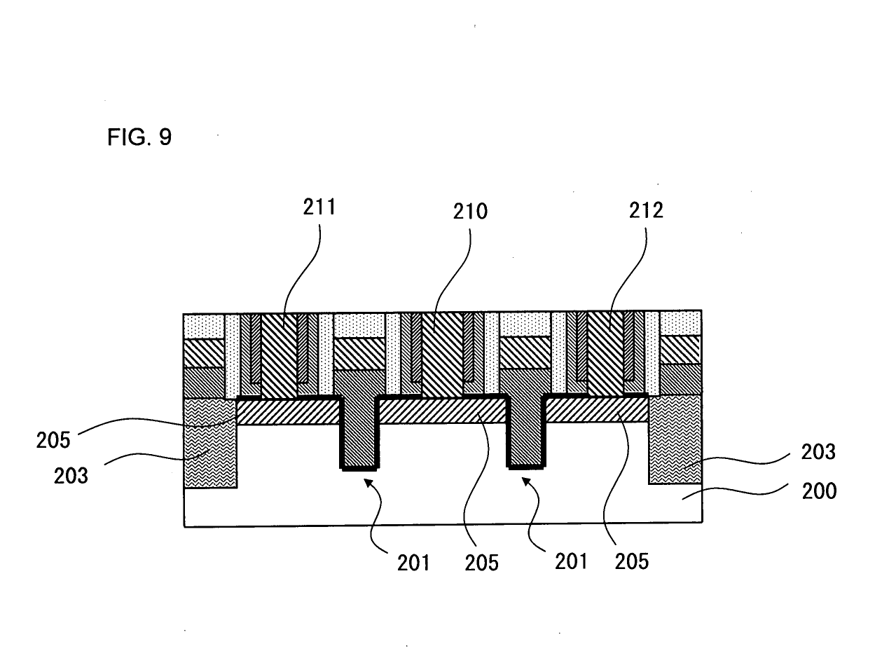

Then, as shown in FIG. 9, a contact hole is formed between gate electrodes 206, and a polycrystalline silicon film doped with impurities such as phosphorous is filled into the contact hole. Thus, contact plugs 210, 211, and 212 connected to N-type impurity layer 205 are simultaneously formed. When contact plugs 210, 211, and 212 are formed, openings reaching N-type impurity layer 205 may be formed by a self-alignment method using cap insulating film 207 and side walls 208 as an etching stopper film.

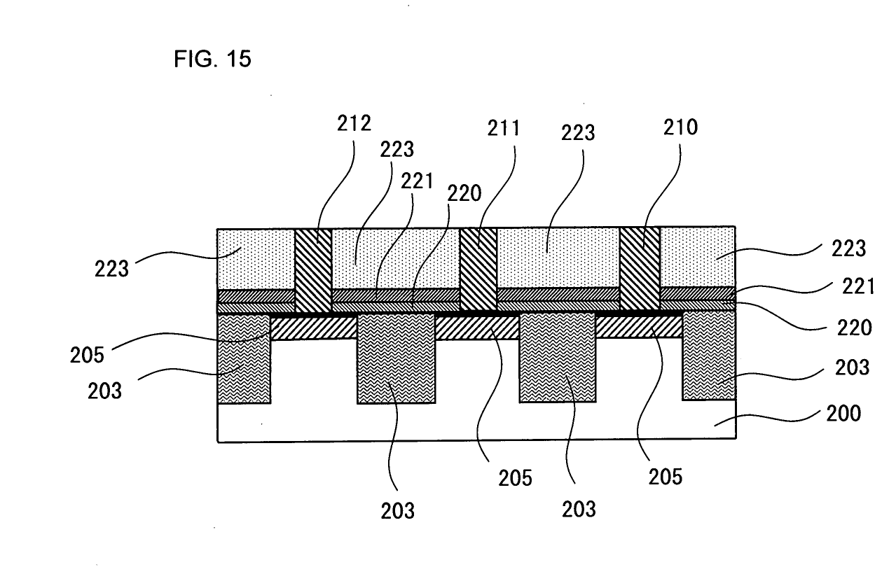

In the present exemplary embodiment, liner film 222 includes the stack structure of upper-layer silicon oxynitride film 221 and lower-layer silicon nitride film 220. Thus, thermal treatment enables SOD film material 223 to be easily converted into a dense insulating film. A cross section corresponding to portion G-G′ of FIG. 10 is shown in FIG. 15. SOD film 223 between the contact plugs is dense. Thus, when the openings (contact holes) for contact plugs 210, 211, and 212 are formed, the openings arranged adjacent to each other in a direction along gate electrode 206 can be prevented from being short-circuited (the region between the openings shown by arrow E in FIG. 4 is prevented from being short-circuited).

Thereafter, as shown in FIG. 10, wiring layer 231 for a bit line, capacitor element 245, upper-layer wiring layer 257, and the like are formed to complete a memory cell for the DRAM.

Even if the interval (the dimension shown at F in FIG. 10) between gate electrodes 206 is 60 nm or less as a result of advanced miniaturization, the application of the present invention enables an SOD film material used as an interlayer insulating film to be easily converted into a dense insulating film. Thus, even when contact holes are formed on an insulating film formed using an SOD film material, the region between the adjacent contact holes can be prevented from being short-circuited. Consequently, a semiconductor device such as a DRAM can be manufactured without reducing manufacturing yield.

Furthermore, in the present exemplary embodiment, the SOD film is fed with oxygen through the silicon oxynitride film in the upper layer portion of the liner film. This eliminates the need to set the temperature of the oxidizing atmosphere for the modification of the SOD film to an excessively large value. This in turn inhibits the possible adverse effect of heat applied to MOS transistor (201) already formed under the interlayer insulating film formed using the SOD film. As a result, the electrical characteristics of the MOS transistor can be prevented from being degraded by the adverse effect of the thermal treatment. Therefore, a semiconductor device such as a high-performance DRAM can be manufactured.

Furthermore, silicon nitride film 220 that is excellent in resistance to oxidation allows each gate electrode 206 and semiconductor substrate 200 to be prevented from being degraded by the oxidizing atmosphere during the thermal treatment.

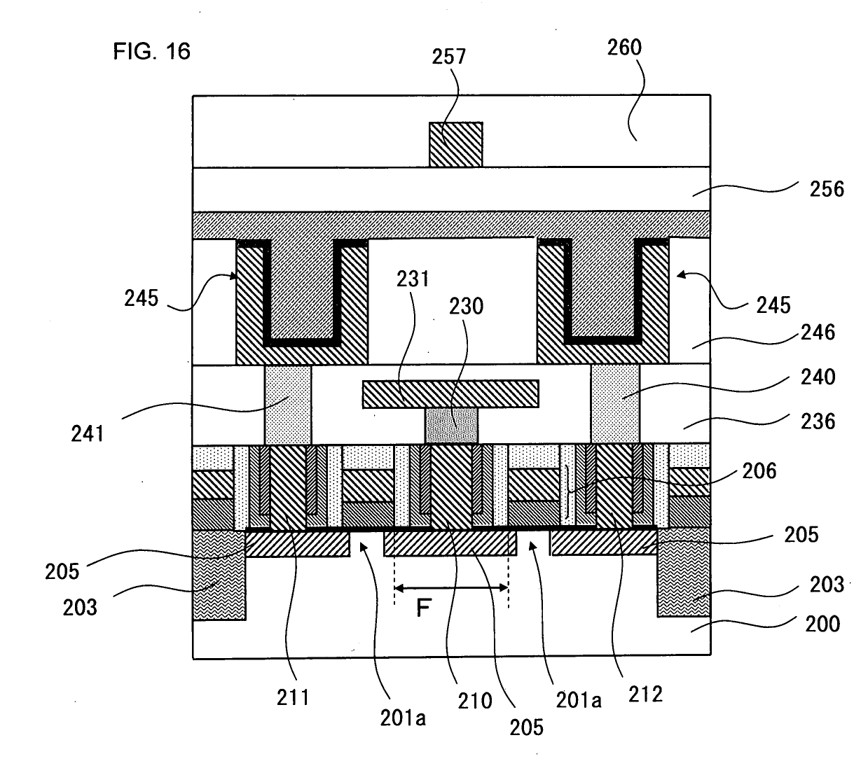

In the description of the present exemplary embodiment, N-type recess channel MOS transistor 201 is used. However, the semiconductor device according to the present exemplary embodiment is not limited to this aspect. That is, as a transistor, the semiconductor device according to the present exemplary embodiment may use a P-type MOS transistor or a planar transistor including gate electrodes 206a not buried in semiconductor substrate 200. A variation using a planar transistor is shown in FIG. 16. Reference numeral 201a denotes a MOS transistor with a planar gate electrode structure.

In the description of the semiconductor device according to the present exemplary embodiment, SOD film 223 is finally removed as shown in a sectional view taken in the direction A-A′ of FIG. 4. However, the present invention is not limited to this aspect. In a variation of the present exemplary embodiment, each of the contact holes may be formed to have a size smaller than the width of the space between the adjacent gate electrodes so that the SOD film partly remains.

### Third Exemplary Embodiment

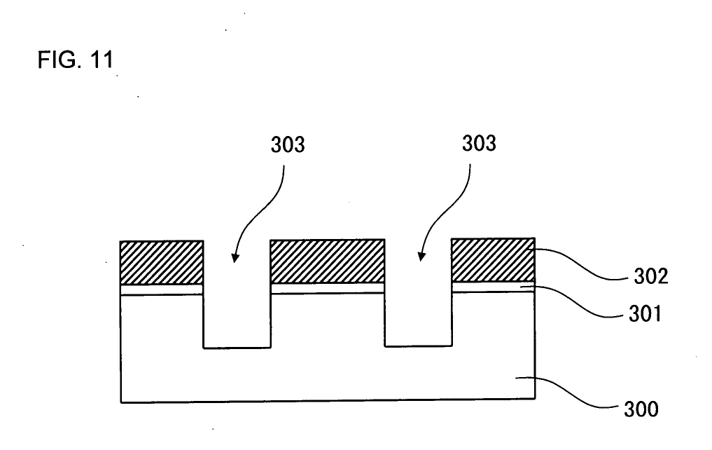

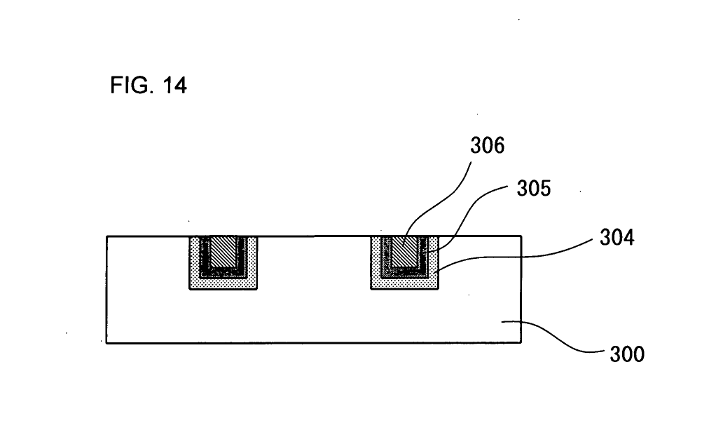

A manufacturing method for isolation region will be described with reference to FIGS. 11 and 14. As shown in FIG. 11, silicon oxide film 301 is formed on semiconductor substrate 300. Then, mask film 302 is formed using a silicon nitride film, and patterning is performed. Semiconductor substrate 300 is then etched using mask film 302 as a mask, to form trenches 303.

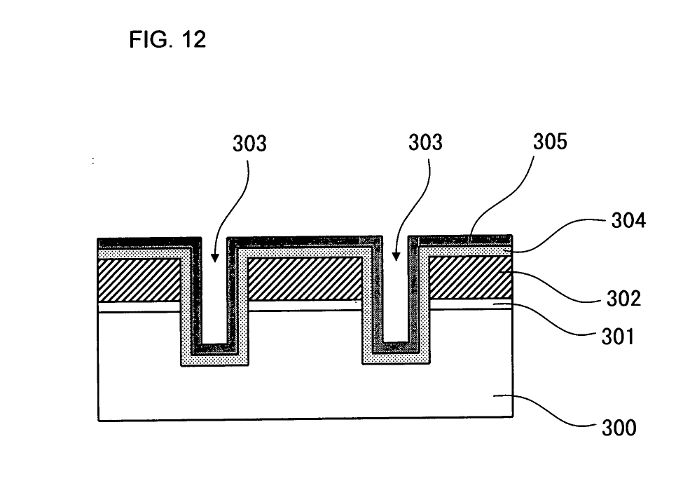

Then, as shown in FIG. 12, silicon nitride film (Si₃N₄) film 304 is formed to a thickness of 3 to 6 nm. Silicon oxynitride film (SiON) 305 is then formed to a thickness of 3 to 10 nm. Silicon nitride film 304 and silicon oxynitride film 305 cover the inside of each trench 303 and the top surface of mask film 302. Silicon nitride film (Si₃N₄) 304 corresponds to a first liner film. Silicon oxynitride film (SiON) 305 corresponds to a second liner film. Alternatively, before silicon nitride film (first liner film) 304 is formed, thermal oxidation may be performed to form an oxide of a semiconductor substrate material on the inner wall of trench 303 as an insulating film with a thickness of about 4 to 8 nm.

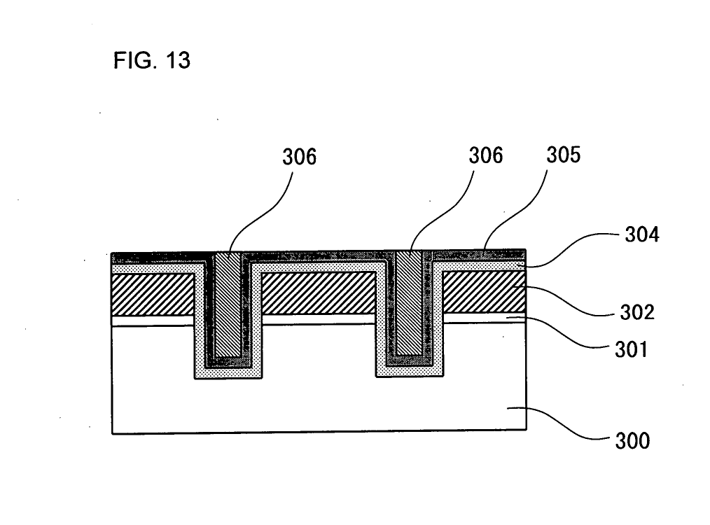

Then, as shown in FIG. 13, SOD film material 306 such as polysilazane is coated to fill the inside of each trench 303. Thereafter, resulting structure is thermally treated at 950° C. in an oxidizing atmosphere containing H₂O, for 10 minutes.

In the present exemplary embodiment, the isolation region is formed before the formation of the other elements. Thus, for example, temperature for the thermal treatment applied to modify SOD film material 306 can be set to a larger value than in the above-described exemplary embodiment. Also in this case, in the present exemplary embodiment, silicon nitride film 304 is provided in the lower layer of the liner film. This enables semiconductor substrate 300 to be prevented from being affected by oxidation. Furthermore, silicon oxynitride film 305 is provided in the upper layer of the liner film. Thus, even with the reduced opening width of trench 303, SOD film 306 can be fed with oxygen through silicon oxynitride film 305 and thus easily converted into a dense insulating film. Additionally, generation of possible ammonia gas from the liner film can be inhibited, thus effectively facilitating efficient conversion into a dense insulating film.

Then, as shown in FIG. 14, the surface of the resulting structure is flattened using the CMP method. Remaining mask film 302 and silicon oxide film 301 are then removed to form isolation regions. Wet etching for removing mask film 302 also removes exposed portions of silicon nitride film 304 and silicon oxynitride film 305. Thus, the time for the wet etching may be adjusted so as to flatten the surfaces of silicon nitride film 304 and silicon oxynitride film 305.

The isolation region manufactured according to the third exemplary embodiment may be applied as isolation region 203 for the second exemplary embodiment.

### Fourth Exemplary Embodiment

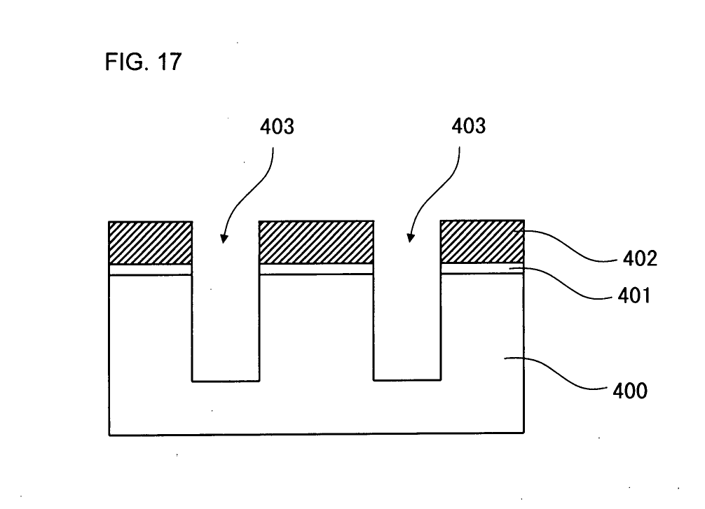

Another method for forming an isolation region will be described with reference to FIGS. 17 to 22.

As shown in FIG. 17, silicon oxide film 401 is formed on semiconductor substrate 400 made up of silicon. Then, mask film 402 is formed using a silicon nitride film, and patterning is performed. Semiconductor substrate 400 is then etched using mask film 402 as a mask, to form trenches 403 with a thickness of about 200 nm.

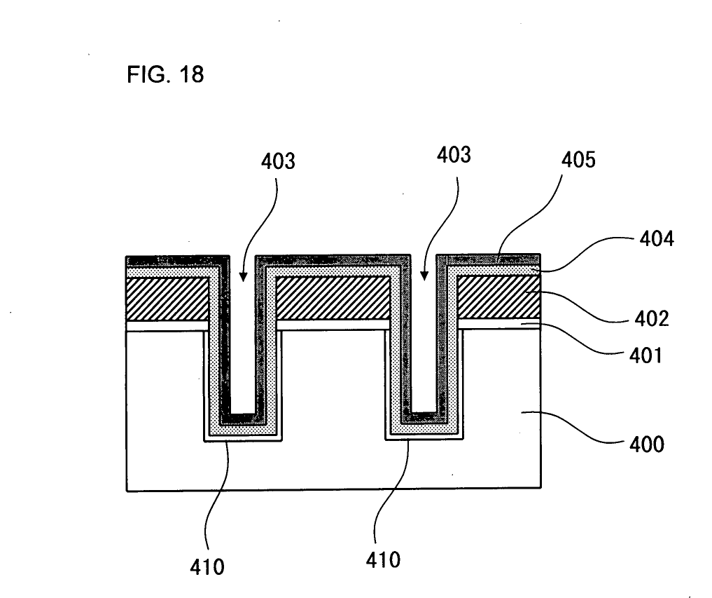

Then, as shown in FIG. 18, a silicon surface exposed inside each trench 403 is thermally oxidized to form silicon oxide film 410 of film thickness about 5 to 8 nm. Thereafter, silicon nitride film (Si₃N₄) 404 of film thickness 3 to 6 nm and silicon oxynitride film (SiON) 405 of film thickness 3 to 10 nm are sequentially deposited, to cover the inside of each trench 403 and the top surface of mask film 402. Silicon nitride film 404 corresponds to a first liner film, and silicon oxynitride film 405 corresponds to a second liner film.

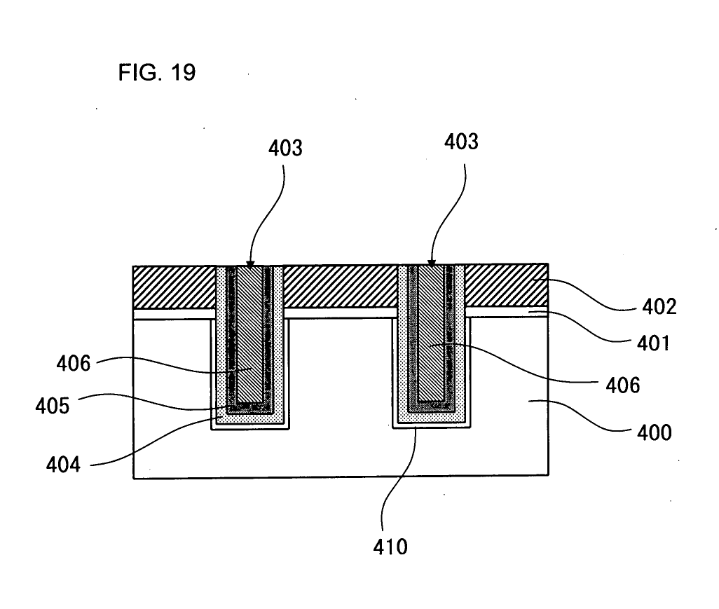

Then, as shown in FIG. 19, an SOD film material such as polysilazane is coated so as to be filled into each trench 403. Thermal treatment is thereafter carried out at 950° C. for 10 minutes in an oxidizing atmosphere containing H₂O. The thermal treatment converts SOD film 406 into a dense insulating film. Polishing is thereafter performed using the CMP method until the top surface of mask film 402 is exposed, with SOD film 406 left inside trench 403.

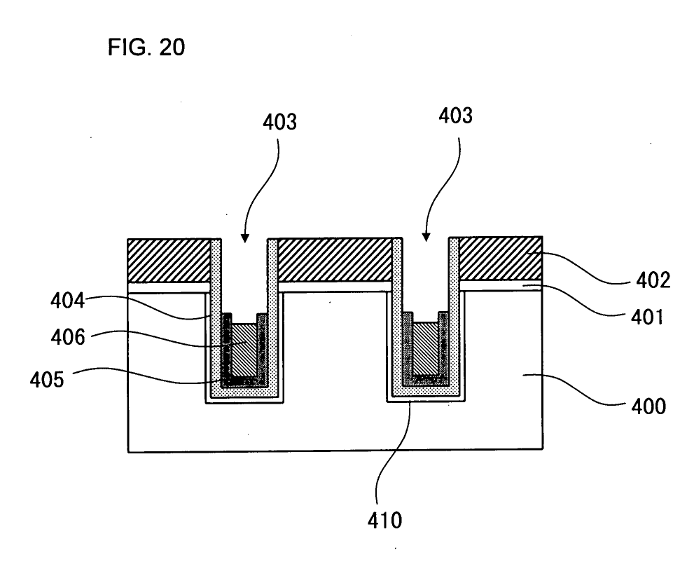

Then, as shown in FIG. 20, a chemical containing hydrofluoric acid (HF) is used to perform wet etching to remove SOD film 406 so that the height of the remaining part of SOD film 406 is equal to about half of the depth of trench 403 down to the bottom thereof. At this time, silicon oxynitride film 405 is also removed by wet etching. However, the rate at which silicon oxynitride film 405 is etched with hydrofluoric acid is lower than that the rate at which SOD film 406 is etched with hydrofluoric acid. Thus, when the wet etching is finished, silicon oxynitride 405 remains so that the top surface of the remaining part of silicon oxynitride 405 is higher than that of a part of SOD film 406 remaining in trench 403. Furthermore, silicon nitride film 404 properly resists etching with hydrofluoric acid. Thus, silicon nitride film 404 resists the etching and thus remains intact.

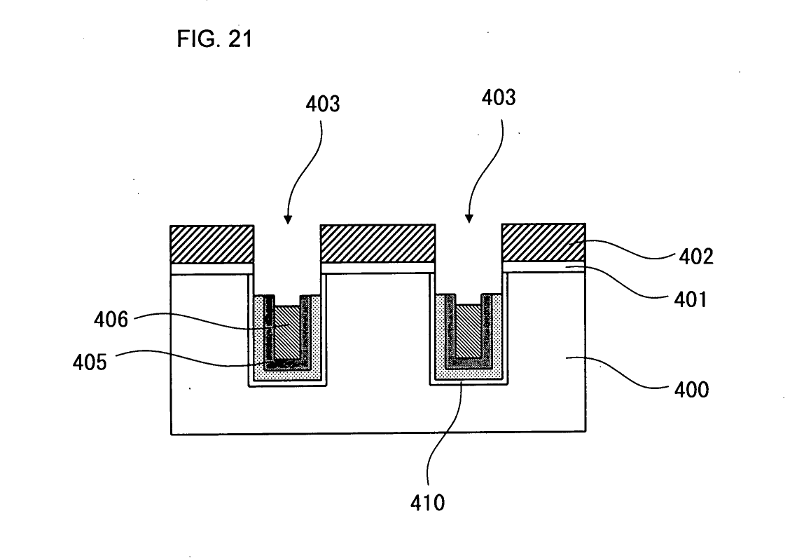

Then, as shown in FIG. 21, a chemical containing phosphoric acid (H₃PO₄) is used to perform wet etching to remove silicon nitride film 404 such that the remaining part of silicon nitride film 404 is substantially as high as that of silicon oxynitride film 405. When exposed to the chemical during the progress of the wet etching, mask film 402 is similarly etched. Thus, preferably the wet etching is temporally controlled so as to minimize the exposure of mask film 402 to the chemical. SOD film 406 and silicon oxynitride film 405 resists the wet etching and are thus prevented from being etched.

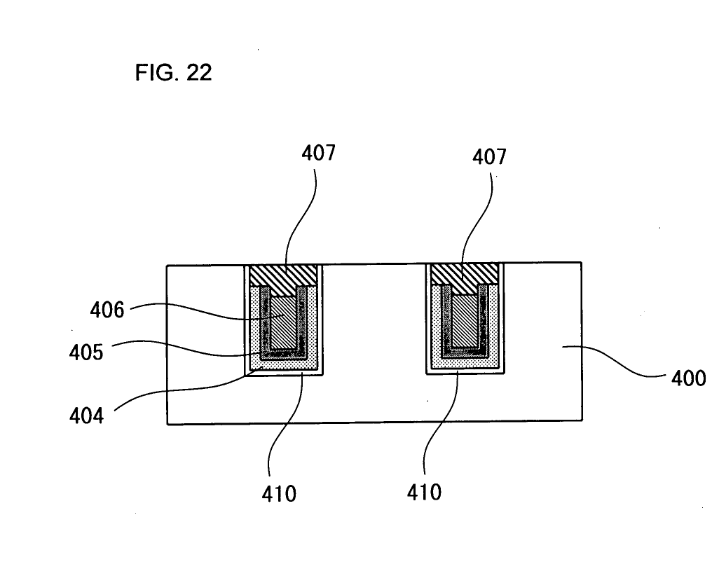

Then, as shown in FIG. 22, silicon oxide film 407 is buried in the upper portion of each trench 403 as an insulating filler using an HDP-CVD (High Density Plasma CVD) method or the like. The resulting structure is flattened by the CMP method. Remaining mask film 402 is then removed. A chemical containing hydrofluoric acid is subsequently used to perform wet etching such that the top surface of silicon oxide film 407 is substantially as high as that of semiconductor substrate 400. An isolation region is thus completed.

In the isolation region formed according to the present exemplary embodiment, only silicon oxide film 407 formed as an insulating filler is exposed from the top surface of the isolation region. First and second liner films (404 and 405) are not exposed from the top surface of the semiconductor substrate.

After the formation of the isolation region composed of the first and second liner films and the SOD film, to form a transistor having thin gate electrodes as shown in the second exemplary embodiment, generally a pattern formed of a silicon nitride film is used as a mask for etching of the semiconductor substrate. When removing this silicon nitride film for masking, the liner film (silicon nitride film) in the already formed isolation region may be etched and recessed by being exposed from the top surface of the semiconductor substrate. A conductor belonging to the gate electrodes is likely to remain in the resulting recess portion and may cause a short circuit between the gate electrodes. In the isolation region in the present exemplary embodiment, the liner film is not exposed from the top surface of the semiconductor substrate. Thus, the formation of such recess portion is prevented, enabling a possible decrease in the manufacturing yield of semiconductor devices to be prevented.

Furthermore, the isolation region described in the present exemplary embodiment may be combined with a MOS transistor with planar gate electrodes instead of the MOS transistor with the thin gate electrodes.

In a conventional liner film with a single layer of a silicon nitride film, modification based on thermal treatment after coating of an SOD film fails to progress sufficiently near the bottom of each trench having a high aspect ratio. Consequently, in the step of wet etching shown in FIG. 20, the rate at which the SOD film located near the bottom of trench 403 is etched with the chemical is very high. It is thus difficult to perform control such that an appropriate film thickness of SOD film is left at the bottom of the trench. When the film thickness (height) of the SOD film left at the bottom of the trench is insufficient, a void is likely to be created when a silicon oxide film is buried in the upper portion of the trench. As a result, using the SOD film as an isolation region is difficult.

In the present exemplary embodiment, the liner film includes the two-layer structure. Thus, the SOD film can be easily converted into a dense insulating film even near the bottom of the trench. This enables the film etching rate for the wet etching to be set within a controllable range.

### Fifth Exemplary Embodiment

A specific example will be described in which a semiconductor element is formed using the isolation region produced according to the third or fourth exemplary embodiment.

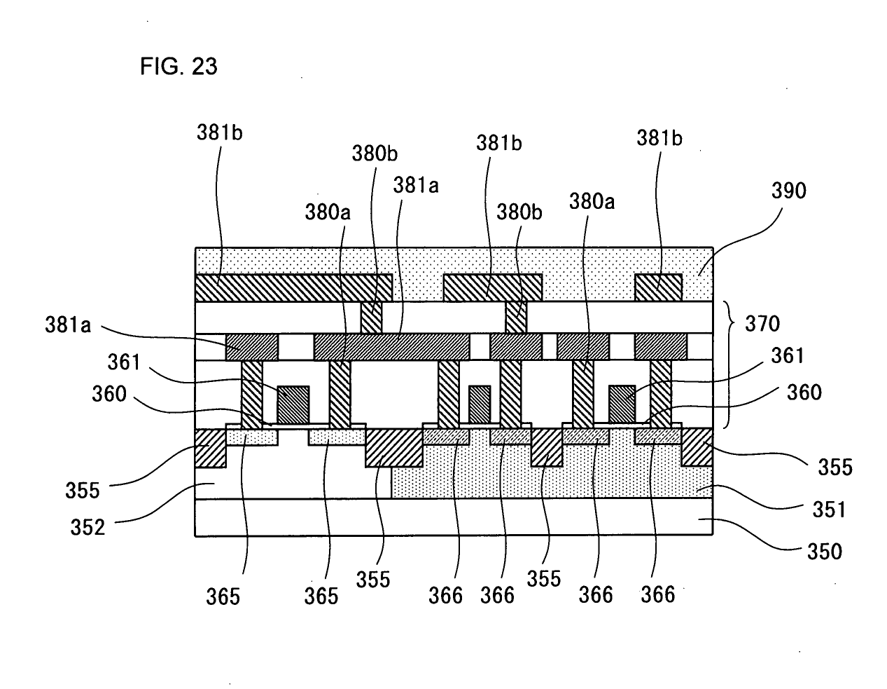

FIG. 23 is a sectional schematic diagram of an arithmetic processing device such as an MPU (Micro Processing Unit) or a DSP (Digital Signal Processor). A plurality of MOS transistors of a CMOS configuration are arranged in the arithmetic processing device to form a circuit for performing predetermined arithmetic operations.

FIG. 23 shows that a MOS transistor includes a planar gate electrode. Reference numeral 350 denotes a semiconductor substrate formed using P-type silicon as a material. P-type well 351 and N-type well 352 are formed in semiconductor substrate 350 by doping impurities into semiconductor substrate 350 by ion implantation. Reference numeral 355 denotes an isolation region described in the third exemplary embodiment and including the structure shown in FIG. 14 (the internal structure of the isolation region is omitted from FIG. 23). The isolation region described in the fourth exemplary embodiment (FIG. 22) may be used as isolation region 355.

Gate electrodes 361 are formed on the surface of semiconductor substrate 350 via respective gate insulating films 360. The gate insulating film may be, for example, a high-K film (high dielectric-constant film) such as HfSiON or a silicon oxide film. The gate electrode may be a metal film containing TiN, W, Ni, TaC, or the like, or a polycrystalline silicon film doped with impurities.

P-type impurities such as boron are doped, by the ion implantation method, into an active region in N-type well 352 partitioned by isolation region 355, to form P-type source and drain regions 365. P-type source and drain regions 365 in N-type well 352 is combined with gate electrode 361 to form a P-type MOS transistor.

N-type impurities such as arsenic are doped, by the ion implantation method, into an active region in P-type well 351 partitioned by isolation region 355, to form N-type source and drain regions 366. N-type source and drain regions 366 in P-type well 351 is combined with gate electrode 361 to form an N-type MOS transistor.

Each transistor may be formed to include side walls formed on side surfaces of gate electrode 361 and source and drain regions of an LDD (Lightly Doped Drain) structure. Reference numeral 370 denotes an interlayer insulating film formed using a silicon oxide film or a low-K film (low dielectric-constant film) and formed by stacking layers.

A plurality of wiring layers (381a and 381b) are formed on the MOS transistor using a metal film such as copper (Cu) or aluminum (Al). FIG. 23 shows two wiring layers, but three or more wiring layers may be provided.

The electrodes of the MOS transistor are electrically connected to wiring layer 381a via contact plugs 380a. Wiring layers 381a and 381b are electrically connected together via contact plugs 380b. The contact plugs may be formed simultaneously with formation of the wiring layers using a dual damascene method. Reference numeral 390 denotes a surface protection film formed of, for example, a stack film of a silicon oxide film and a silicon nitride film.

The present exemplary embodiment allows an isolation region suitable for miniaturization to be easily formed. Thus, by forming an arithmetic processing device to which the present exemplary embodiment is applied, transistor elements can be highly integrated together for mounting. As a result, a device with advanced arithmetic processing performance can be manufactured.

Using an arithmetic processing device produced as described above allows formation of, for example, a data processing system described below.

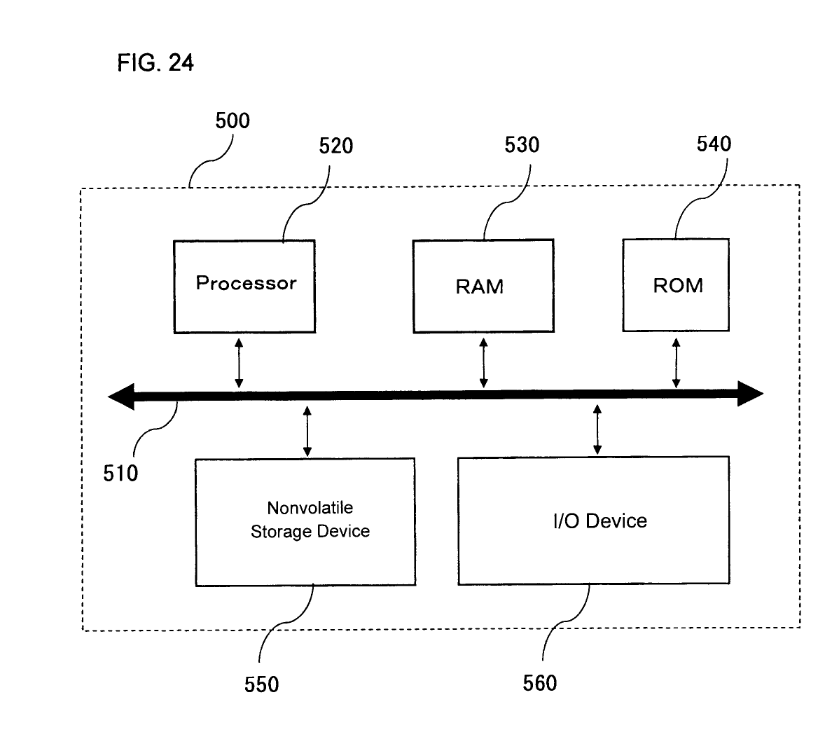

FIG. 24 is a schematic diagram of the configuration of data processing system 500 according to the present exemplary embodiment. Data processing system 500 includes arithmetic processing device 520 and RAM (Random Access Memory) 530 connected together via system bus 510. Arithmetic processing device 520 is an MPU, a DSP, or the like formed as described above. A DRAM element or an SRAM element can be utilized as a RAM.

Furthermore, to allow fixed data to be stored, ROM (Read Only Memory) 540 may be connected to system bus 510. Only one system bus 510 is illustrated for simplicity. However, system buses 510 may be connected together in series or parallel via connectors or the like as required. Additionally, devices may be connected together via a local bus without using system bus 510.

Furthermore, in data processing system 500, nonvolatile storage device 550 and I/O device 560 are connected to system bus 510 as required. The nonvolatile storage device may be a hard disk, an optical drive, an SSD (Solid State Drive), or the like.

I/O device 560 includes, for example, a display device such as a liquid crystal display and a data input device such as a keyboard. For each of the components of the system, FIG. 24 shows only one piece for simplification. However, the present exemplary embodiment is not limited to this aspect. For all or any of the components of the system, a plurality of pieces may be provided.

In the present exemplary embodiment, the data processing system includes, for example, a computer system. However, the present exemplary embodiment is not limited to this aspect.

In the above-described first to fifth exemplary embodiments, polysilazane is used as an SOD film material. Polysilazane includes a molecular structure in which a nitrogen atom (N) and a hydrogen atom (H) are bonded to a silicon atom (Si). When polysilazane is subjected to a hot steam oxidation treatment, an Si—O bond is formed to convert the polysilazane into a solid film of dense film quality. In the present invention, oxygen can be fed to the SOD film material through the second liner film provided under the SOD film material. Thus, any material other than polysilazane may be used provided that the material is a coating insulating film that is solidified when thermally treated in an oxidizing atmosphere.

Moreover, any coating film containing at least silicon atoms and nitrogen atoms can be more effectively converted into a solid insulating film by applying the present invention to the coating film provided that when the coating film is exposed to hot steam, Si—N bonds in the coating film are converted into Si—O bonds. In this case, the second liner film preferably contains a reduced amount of nitrogen atoms.

If a silicon oxynitride film (SiON) is used as a second liner film, the composition ratio of oxygen atoms and nitrogen atoms in the film can be adjusted by changing the flow ratio of material gases during film formation. Thus, a silicon oxynitride film in which the number of oxygen atoms is larger than that of nitrogen atoms (for example, a silicon oxynitride film in which the number of oxygen atoms is three to six times as large as that of nitrogen atoms) can be effectively used as a second liner film. The acid resistance of the film decreases consistently as the rate of the nitrogen atoms in the silicon oxynitride film decreases. However, the present invention uses a stack structure of a first and second liner films, thus enabling hot oxidation treatment on the SOD film material without affecting the underlying layer.

It is apparent that the present invention is not limited to the above embodiments, but may be modified and changed without departing from the scope and spirit of the invention.

What is claimed is:

1. A semiconductor device comprising:
a recess portion;
a first liner film formed on opposite inner wall side surfaces and a bottom surface of the recess portion;
a second liner film formed on the first liner film in the recess portion; and
an insulating region comprising an SOD film filled in the recess portion,
wherein the second liner film contains an oxygen atom, and the first liner film has a higher oxidation resistance than the second liner film.

2. The semiconductor device according to claim 1, further comprising a semiconductor substrate, a first interlayer insulating film provided on the semiconductor substrate, and a plurality of wiring layers provided on the first interlayer insulating film,
wherein the recess portion is a space portion between the adjacent wiring layers,
the opposite inner wall side surfaces of the recess portion are opposite side surfaces of the adjacent wiring layers,
the bottom surface of the recess portion is composed of the first interlayer insulating film between the adjacent wiring layers, and
the first and second liner films and the SOD film form a second interlayer insulating film.

3. The semiconductor device according to claim 1, wherein the recess portion is a trench formed in a semiconductor substrate,
the opposite inner wall side surfaces and the bottom surface of the recess portion are inner wall side surfaces and a bottom surface of the trench, respectively, and
the first and second liner films and the SOD film form an isolation region.

4. The semiconductor device according to claim 1, further comprising:
a semiconductor substrate;
a plurality of semiconductor protruding portions protruding upward from a predetermined plane positioned in parallel to an upper surface of the semiconductor substrate, the semiconductor protruding portions extending on the predetermined plane in a first direction;
a separating insulating film buried on the predetermined plane between the adjacent semiconductor protruding portions;
source/drain regions provided in each semiconductor protruding portion;
a plurality of contact plugs, each of the contact plugs being electrically connected to the corresponding source/drain regions;
a plurality of gate electrodes provided over the separating insulating film and the semiconductor protruding portions in a second direction being different from the first direction such that the contact plug is located between the two adjacent gate electrodes; and
a gate insulating film provided between each of the semiconductor protruding portions and a corresponding one of the gate electrodes,
wherein the semiconductor protruding portion, the gate electrode, the gate insulating film, and the source/drain regions form a field effect transistor, and
the recess portion is a space portion between the adjacent gate electrodes.

5. The semiconductor device according to claim 4, wherein the opposite inner wall side surfaces of the recess portion are side surfaces of the adjacent gate electrodes, and
another insulating film is provided between the side surface of each of the gate electrodes and the first liner film.

6. The semiconductor device according to claim 4, wherein side walls are further provided on the side surfaces of each of the gate electrodes, and
the opposite inner wall side surfaces of the recess portion are opposite side surfaces of the side walls provided on the side surfaces of the adjacent gate electrodes.

7. The semiconductor device according to claim 4, wherein the bottom surface of the recess portion is composed of the gate insulating film provided on the separating insulating film between the adjacent gate electrodes.

8. The semiconductor device according to claim 4, wherein each of the gate electrodes further comprises a conductive portion buried down to an inside of a corresponding one of the semiconductor protruding portions,
the gate insulating film further comprises an insulating film formed between the conductive portion and the semiconductor protruding portion, and
the field effect transistor is of a recess channel type.

9. A semiconductor device comprising:
a semiconductor substrate; and
an isolation region formed in the semiconductor substrate,
wherein the isolation region comprises a first liner film formed so as to continuously cover at least a part of an inner wall of a trench formed in the semiconductor substrate, a second liner film provided on the first liner film and containing an oxygen atom, and an insulating region comprising an SOD film filled in at least a part of an inside of the trench so as to be in contact with the second liner film, and
the first liner film has a higher oxidation resistance than the second liner film.

10. The semiconductor device according to claim 9, wherein the isolation region comprises:
the first liner film, the second liner film, and the insulating region which are provided in a lower portion of an inside of the trench formed in the semiconductor substrate; and
an insulating filler formed in an upper portion of the inside of the trench and covering the first liner film, the second liner film, and the insulating region, and
top surfaces of the first and second liner films and the insulating region are all positioned below a top surface of the semiconductor substrate.

11. The semiconductor device according to claim 10, wherein the insulating filler comprises a silicon oxide film.

12. The semiconductor device according to claim 1, wherein the SOD film is a silicon oxide film.

13. The semiconductor device according to claim 1, wherein the first liner film is a silicon nitride film, and
the second liner film is a silicon oxynitride film.

14. The semiconductor device according to claim 1, wherein both the first and second liner films contain a nitrogen atom, and
nitrogen atom content of the second liner film is smaller than nitrogen atom content of the first liner film.

15. The semiconductor device according to claim 13, wherein the silicon oxynitride film contains more oxygen atoms than nitrogen atoms.

16. The semiconductor device according to claim 9, wherein the first liner film is a silicon nitride film,
the second liner film is a silicon oxynitride film, and
the second liner film contains more oxygen atoms than nitrogen atoms.

17. A method for manufacturing a semiconductor device, comprising:
forming a recess portion;
forming a first liner film covering opposite inner wall side surfaces and a bottom surface of the recess portion;
forming a second liner film covering the first liner film; and
filling an SOD film covering the second liner film in the recess portion,
wherein the second liner film contains an oxygen atom, and
the first liner film has a higher oxidation resistance than the second liner film.

18. The method for manufacturing a semiconductor device according to claim 17, wherein in forming the recess portion,
a first interlayer insulating film is formed on a semiconductor substrate,
a plurality of wiring layers are formed on the first interlayer insulating film,
the recess portion is formed as a space portion between the adjacent wiring layers,
the opposite inner wall side surfaces of the recess portion are opposite side surfaces of the adjacent wiring layers, and
the bottom surface of the recess portion is composed of the first interlayer insulating film between the adjacent wiring layers.

19. The method for manufacturing a semiconductor device according to claim 17, wherein in forming the recess portion,
the semiconductor substrate is partly removed to form a trench in the semiconductor substrate,
the recess portion is formed as the trench, and
the opposite inner wall side surfaces and the bottom surface of the recess portion are inner wall side surfaces and a bottom surface of the trench, respectively.

20. The method for manufacturing a semiconductor device according to claim 19, between forming the recess portion and forming the first liner film, further comprising:
oxidixzing the opposite inner wall side surfaces and the bottom surface of the trench.

21. The method for manufacturing a semiconductor device according to claim 17, wherein the first liner film is a silicon nitride film, and
the second liner film is a silicon oxynitride film.

22. The method for manufacturing a semiconductor device according to claim 17, wherein the first and second liner films contain a nitrogen atom, and
nitrogen atom content of the second liner film is smaller than nitrogen atom content of the first liner film.

23. The method for manufacturing a semiconductor device according to claim 17, wherein polysilazane is subjected to thermal treatment in an oxidizing atmosphere, to form the SOD film.

24. A data processing system including an arithmetic processing device,
wherein the arithmetic processing device comprises:
a recess portion;
a first liner film formed on opposite inner wall side surfaces and a bottom surface of the recess portion;
a second liner film formed on the first liner film in the recess portion; and
an insulating region comprising an SOD film filled in the recess portion,
wherein the second liner film contains an oxygen atom, and the first liner film has a higher oxidation resistance than the second liner film.

25. The data processing system according to claim 24, wherein the recess portion is a trench formed in a semiconductor substrate,
the opposite inner wall side surfaces and the bottom surface of the recess portion are inner wall side surfaces and a bottom surface of the trench, respectively, and
the first and second liner films and the SOD film form an isolation region.
